(19) United States
(12) Patent Application Publication
(10) Pub. No.: US 2016/0071947 A1
(43) Pub. Date: Mar. 10, 2016

(54) METHOD INCLUDING A REPLACEMENT OF A DUMMY GATE STRUCTURE WITH A GATE STRUCTURE INCLUDING A FERROELECTRIC MATERIAL

(71) Applicant: GLOBALFOUNDRIES Inc., Grand Cayman (KY)

(72) Inventors: Maciej Wiatr, Dresden (DE); Stefan Flachowsky, Dresden (DE)

(21) Appl. No.: 14/482,839

(22) Filed: Sep. 10, 2014

(51) Int. Cl. H01L 29/51; H01L 21/8234; H01L 29/66; H01L 27/088

(52) U.S. Cl. CPC H01L 29/516; H01L 27/088; H01L 21/823462; H01L 29/66545

(57) ABSTRACT

A method disclosed herein includes providing a substrate including a semiconductor material. A first area of the substrate is recessed relative to a second area of the substrate, and an active region of a first transistor is formed in the recessed area. An active region of a second transistor is formed in the second area of the substrate. First and second dummy gate structures are formed over the active regions of the first transistor and the second transistor, respectively. At least a portion of the first and second dummy gate structures is replaced with at least a portion of a gate structure of the first transistor and the second transistor, respectively. The gate structure of the first transistor includes a ferroelectric material, and the gate structure of the second transistor does not include a ferroelectric material.

### BACKGROUND OF THE INVENTION

1. Field of the Invention

Generally, the present disclosure relates to integrated circuits, and, in particular, to integrated circuits including both transistors having a ferroelectric dielectric and other transistors.

2. Description of the Related Art

Integrated circuits typically include a large number of circuit elements which include, in particular, field effect transistors. The circuit elements in an integrated circuit may be electrically connected by means of electrically conductive metal lines formed in an interlayer dielectric material. The electrically conductive metal lines may be provided in a plurality of interconnect layers that are stacked on top of each other above a substrate in and on which field effect transistors, and other circuit elements, such as capacitors, diodes and resistors, are formed. Metal lines in different interconnect layers may be electrically connected with each other by means of contact vias that are filled with metal.

Integrated circuits may include nonvolatile memory. In some types of nonvolatile memory, so-called ferroelectric transistors (FeFETs) may be employed. Ferroelectric transistors may include a gate structure that is formed above a channel region provided between a source region and a drain region, wherein the gate structure includes a ferroelectric material.

In some types of ferroelectric transistors, a gate electrode may be provided in the gate structure over the ferroelectric material, with no electrically conductive materials being provided between the channel region and the ferroelectric material.

In other types of ferroelectric transistors, an electrically conductive floating gate electrode may be provided between the ferroelectric material and the channel region, and a further gate electrode that is electrically connected to other circuit elements may be provided over the ferroelectric material. A ferroelectric memory element wherein metallic electrodes serve as a floating gate and bottom electrode is described in U.S. Pat. No. 5,877,977.

An electrical conductivity of the channel region of a ferroelectric transistor may be controlled by an electrical field that acts on the channel region. In addition to an electrical field that is created by applying a gate voltage to the gate electrode of the ferroelectric transistor, an electrical field caused by a ferroelectric polarization of the ferroelectric material in the gate structure may also act on the channel region of the ferroelectric transistor.

Depending on the direction of the ferroelectric polarization of the ferroelectric material, the electrical field created by the ferroelectric polarization of the ferroelectric material may have a substantially same direction as the electrical field created by the application of the gate voltage to the gate electrode, or the electrical field created by the ferroelectric polarization of the ferroelectric material and the electrical field created by the application of the gate voltage to the gate electrode may have substantially opposite directions.

If both electrical fields have substantially the same direction, a threshold voltage that needs to be applied to the gate electrode for switching the ferroelectric transistor into the electrically conductive state (for ferroelectric transistors being N-channel transistors, the transistor is switched into the electrically conductive state by applying a positive gate voltage) may be reduced, and the electrical conductivity of the channel region that is obtained when a particular gate voltage greater than the threshold voltage is applied may be increased. If both electrical fields have opposite directions, the threshold voltage of the ferroelectric transistor may be increased, and the electrical conductivity of the channel region that is obtained when a particular gate voltage greater than the threshold voltage is applied may be reduced.

The ferroelectric polarization of the ferroelectric material may be influenced by applying a programming voltage between the gate electrode and the channel region. For example, the programming voltage may be applied to the gate electrode, and the source region, the drain region and, optionally, the body of the ferroelectric transistor may be maintained at mass potential. The programming voltage may be positive or negative, depending on the desired direction of the ferroelectric polarization of the ferroelectric material. A remanent polarization of the ferroelectric material may be maintained even if the programming voltage is no longer applied. Thus, a bit of data may be stored in the ferroelectric transistor, wherein a first polarization direction of the ferroelectric material may be identified with a logical 0 and a second polarization direction of the ferroelectric material may be identified with a logical 1.

For reading the stored bit of data from the ferroelectric transistor, a gate voltage (which may be approximately equal to zero or different from zero) may be applied between the gate electrode and the source region of the ferroelectric transistor. If the gate voltage applied during the reading of the bit of data is different from zero, it is typically lower than the programming voltage, so that the ferroelectric polarization of the ferroelectric dielectric is substantially not changed. Then, the electric current flowing through the ferroelectric transistor may be measured for determining the direction of the ferroelectric polarization of the ferroelectric material.

For some applications, it may be desirable to form ferroelectric transistors and field effect transistors of other types on the same semiconductor substrate. For example, in U.S. Patent Publication No. 2013/0270619, a method is disclosed wherein a high-k dielectric layer is formed above a first active region and a second active region so as to serve as a ferroelectric layer. The high-k dielectric layer is removed from above the first active region. The high-k dielectric layer is preserved above the second active region. A first electrode structure is formed above the first active region, and a second electrode structure is formed above the second active region.

When ferroelectric transistors and other transistors, such as standard CMOS devices, are formed in the same semiconductor structure, it may be desirable to provide a height of the gate structures of the ferroelectric transistors that is greater than a height of the gate structures of other transistors. These different heights of the gate structures may cause issues in the manufacturing of the semiconductor structure.

The present disclosure provides methods for the manufacture of semiconductor structures and semiconductor structures wherein such issues are at least partially overcome.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method disclosed herein includes providing a substrate including a semiconductor material. A first area of the substrate is recessed relative to a second area of the substrate. An active region of a first transistor is formed in the recessed first area of the substrate. An active region of a second transistor is formed in the second area of the substrate. A first dummy gate structure is formed over the active region of the first transistor. A second dummy gate structure is formed over the active region of the second transistor. At least a portion of the first dummy gate structure is replaced with at least a portion of a gate structure of the first transistor. At least a portion of the second dummy gate structure is replaced with at least a portion of a gate structure of the second transistor. The gate structure of the first transistor includes a ferroelectric material, and the gate structure of the second transistor does not include a ferroelectric material.

An illustrative semiconductor structure disclosed herein includes a semiconductor substrate, a first transistor and a second transistor. The first transistor includes an active region and a gate structure arranged over the active region. The gate structure of the first transistor includes a floating gate electrode, a ferroelectric material provided over the floating gate electrode and a control gate electrode provided over the ferroelectric material. The second transistor includes an active region and a gate structure arranged over the active region. The gate structure of the second transistor does not include a ferroelectric material. The active region of the first transistor is provided in a first area of the substrate. The active region of the second transistor is provided in a second area of the substrate. The first area is recessed relative to the second area.

### BRIEF DESCRIPTION OF THE DRAWINGS

The disclosure may be understood by reference to the following description taken in conjunction with the accompanying drawings, in which like reference numerals identify like elements, and in which:

FIGS. 1-6 show schematic cross-sectional views of a semiconductor structure according to an embodiment in stages of a manufacturing process according to an embodiment; and

FIG. 7 shows a schematic cross-sectional view of a semiconductor structure according to an embodiment in a stage of manufacturing process according to an embodiment.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

Embodiments disclosed herein relate to ferroelectric transistors which may be used, for example, in ferroelectric transistor memory cells. A remanent ferroelectric polarization of a ferroelectric material provided in a gate electrode of the ferroelectric transistor can directly affect the charges in the channel of the ferroelectric transistor and lead to a defined shift of the output characteristics of the transistor.

Ferroelectric transistors disclosed herein may include HfO₂-based ferroelectric materials, which may be integrated into typical high-k metal gate (HK/MG) process flows. Between the HfO₂ and silicon, a buffer layer including silicon dioxide may be provided.

To overcome integration challenges in embedded process flows wherein ferroelectric transistors and standard complementary metal-oxide-semiconductor (CMOS) transistors are implemented at the same time, which may be caused by different gate stack heights of the ferroelectric transistors and the standard CMOS transistors, in particular, in chemical mechanical polishing processes performed in gate-last process flows, methods and devices according to embodiments disclosed herein may be used.

In some embodiments, a recessed ferroelectric field effect transistor is formed, wherein the silicon surface of the substrate is locally etched back at an early stage of the process flow, so that the top of the thicker ferroelectric gate stack is on the same level as the standard CMOS gate. Thus, conventional chemical mechanical polishing processes may be employed, and topography differences may be avoided. In some embodiments, this concept may be applied to floating gate ferroelectric transistor designs, wherein the gate stack height difference may be more pronounced than in ferroelectric transistors without a floating gate electrode.

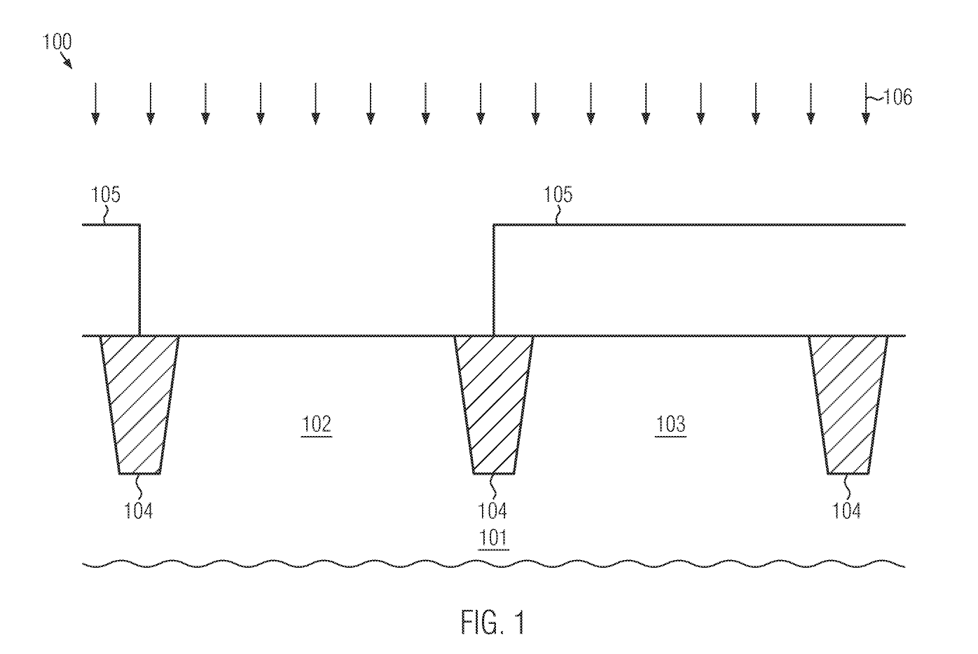

FIG. 1 shows a schematic cross-sectional view of a semiconductor structure 100 according to an embodiment in a stage of a manufacturing process according to an embodiment. The semiconductor structure 100 includes a semiconductor substrate 101. The substrate 101 may include a semiconductor material such as, for example, silicon. In some embodiments, the substrate 101 may be a silicon wafer or die having a thickness direction, wherein an extension of the substrate 101 in the thickness direction is smaller than any extension of the substrate 101 in any direction other than the thickness direction. In the view of FIG. 1, the thickness direction of the substrate 101 is vertical. A main surface of the substrate 101, at which circuit elements of the semiconductor structure 100 will be formed, may be substantially perpendicular to the thickness direction (horizontal in the view of FIG. 1).

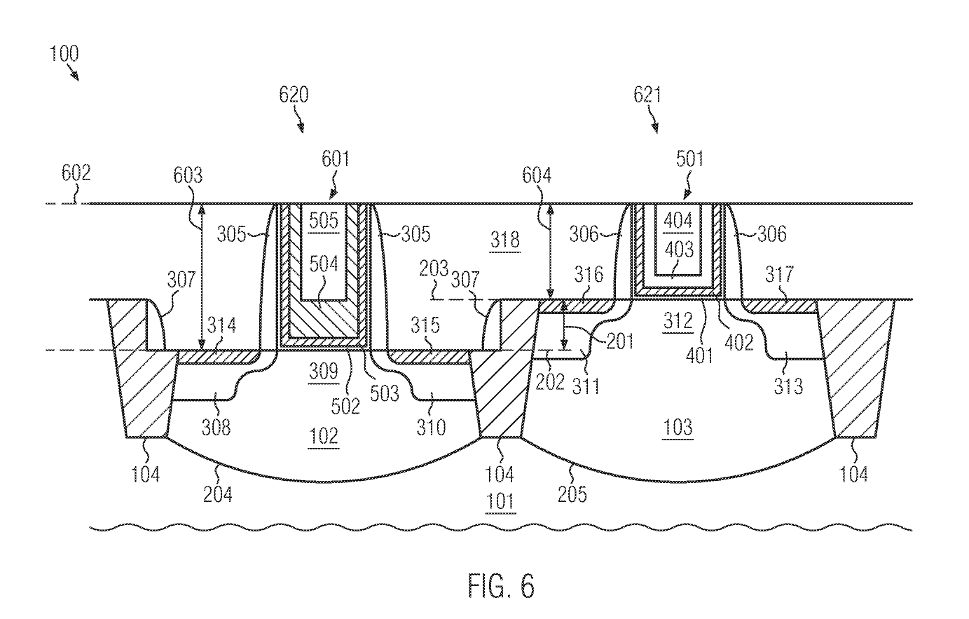

The substrate 101 includes a first area 102 and a second area 103. As will be detailed in the following, in the area 102 of the substrate 101, a ferroelectric transistor having a gate structure including a ferroelectric material will be formed. In the area 103, a transistor 621 other than a ferroelectric transistor, for example a transistor of a complementary metal oxide semiconductor (CMOS) circuit, will be formed (see FIG. 6). The transistor 621 formed in the area 103 may, for example, be a logic transistor that is part of a logic circuit of the semiconductor structure 100 or an input/output transistor that is part of an input/output circuit of the semiconductor structure 100. The gate structure of the transistor 621 formed in the area 103 need not include a ferroelectric material.

In some embodiments, the area 102 of the substrate 101 may be an area of a memory cell of a nonvolatile memory wherein ferroelectric transistors are used for storing bits of data. In particular, a ferroelectric transistor 620 (see FIG. 6) may be formed in the area 102 of the substrate 101. The ferroelectric transistor 620 may be used for storing one bit of data that is represented by a value of a remanent polarization of the ferroelectric material in the gate structure of the transistor 620.

The semiconductor structure 100 further includes a trench isolation structure 104. The trench isolation structure 104 provides electrical insulation between the areas 102, 103 of the substrate 101 and between the areas 102, 103 and other areas of the substrate 101 wherein further circuit elements (not shown) will be formed. The trench isolation structure 104 may be formed by means of known techniques for forming shallow trench isolation structures, which may include photolithography, etching, oxidation, deposition and/or polishing.

A mask 105 may be formed over the substrate 101. The mask 105 may cover the area 103 of the substrate 101, but not the area 102, so that the semiconductor material of the substrate 101 is exposed in the area 102. Moreover, as shown in FIG. 1, parts of the trench isolation structure 104 adjacent the area 102 of the substrate 101 may be exposed. The mask 105 may be a photomask, and it may be formed by means of known techniques of photolithography.

After the formation of the mask 105, an etch process may be performed, as schematically illustrated by arrows 106 in FIG. 1. The etch process 106 may be adapted to remove the material of the substrate 102. In some embodiments, the etch process 106 may be a reactive ion etch process adapted to remove silicon. Optionally, the reactive ion etch process may be adapted to also remove a material of the trench isolation structure 104 which, in some embodiments, may include silicon dioxide.

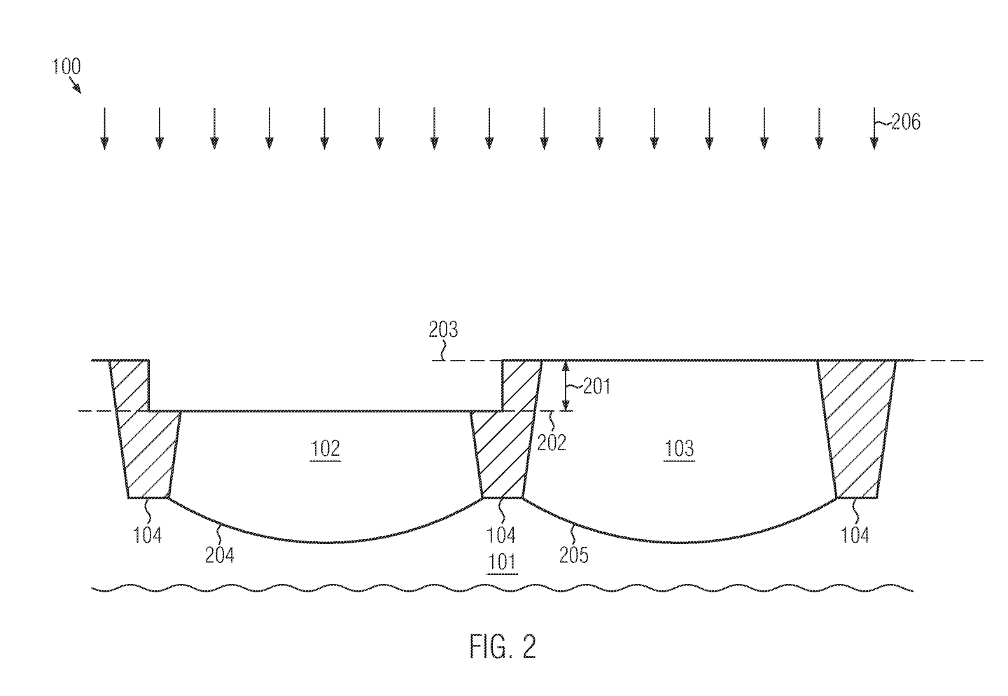

FIG. 2 shows a schematic cross-sectional view of the semiconductor structure 100 in a later stage of the manufacturing process. Due to the removal of material of the substrate 101 in the area 102 that is not covered by the mask 105, the area 102 of the substrate 101 may be recessed relative to the area 103. In particular, after the etch process 106, a surface of the area 102 may be approximately in a plane 202, whereas a surface of the area 103 may be approximately in a plane 203. The plane 203 may substantially correspond to a plane of the initial surface of the substrate 101. Due to the removal of material from the area 102, the plane 202 may be below the plane 203 and substantially parallel to the plane 203, a distance between the planes 202, 203 corresponding to a depth 201 by which the active area 102 was recessed relative to the area 103.

In embodiments wherein the mask 105 does not completely cover portions of the trench isolation structure 104 adjacent the area 102 of the substrate 101, and wherein the etch process 106 is suitable for removing the material of the trench isolation structure 104, portions of the trench isolation structure 104 adjacent the area 102 of the substrate 101 may also be recessed in the etch process 106, as schematically illustrated in FIG. 2. Depending on whether the etch rate of the material of the trench isolation structure 104 is approximately equal to, greater or smaller than the etch rate of the material of the substrate 101, the portions of the trench isolation structure 104 adjacent the area 102 of the substrate 101 may be recessed to approximately the same depth as the depth 201 by which the area 102 of the substrate 101 is recessed relative to the area 103, or to a greater or smaller depth.

After the etch process 106, one or more ion implantation processes may be performed, as schematically denoted by arrows 206 in FIG. 2. In the one or more ion implantation processes, ions of one or more dopant materials may be introduced into the areas 102, 103 of the substrate 101, so that a doped active region 204 is formed in the area 102, and a doped active region 205 is formed in the area 103.

In some embodiments, the active regions 204, 205 may be doped differently. In such embodiments, one of the areas 102, 103 of the substrate 101 may be covered by a mask, for example a photomask, while ions are implanted into the other of the areas 102, 103.

In other embodiments, the one or more ion implantation processes 206 may be omitted. In such embodiments, active regions 204, 205 which are substantially undoped at the stage of the manufacturing process illustrated in FIG. 2 may be provided in the areas 102, 103 of the substrate 101 wherein the original doping of the active regions 204, 205 substantially corresponds to the base doping of the substrate 101.

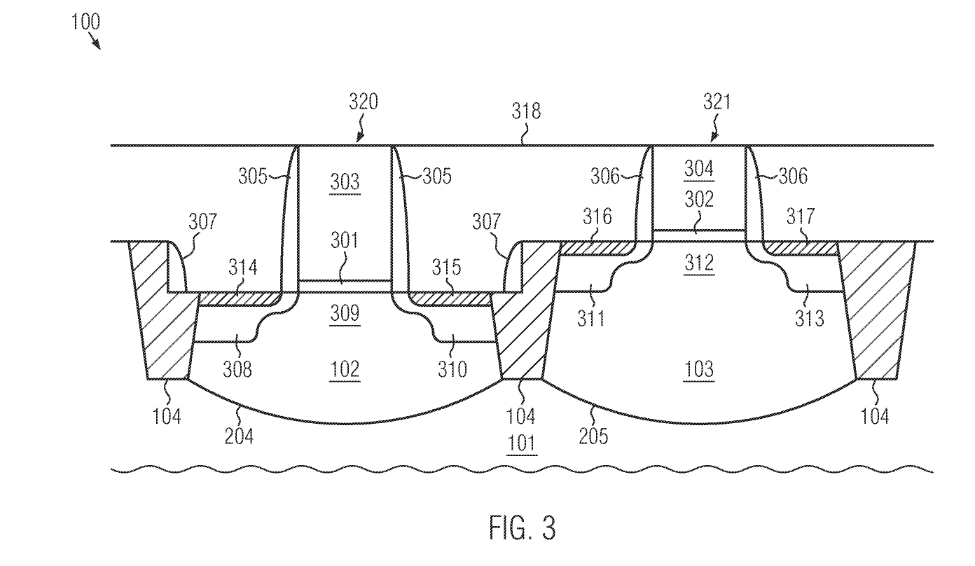

FIG. 3 shows a schematic cross-sectional view of the semiconductor structure 100 in a later stage of the manufacturing process. A first dummy gate structure 320 may be formed over the active region 204, and a second dummy gate structure 321 may be formed over the active region 205. The dummy gate structure 320 may include a dummy gate insulation layer 301 and a dummy gate electrode 303. The dummy gate structure 321 may include a dummy gate insulation layer 302 and a dummy gate electrode 304. In some embodiments, the dummy gate structures 320, 321 may include other components in addition to the dummy gate insulation layers 301, 302 and the dummy gate electrodes 303, 304. For example, in some embodiments, the dummy gate structures 320, 321 may include cap layers which are provided over the dummy gate electrodes 303, 304.

For forming the dummy gate structures 320, 321, a dummy gate stack may be deposited over the semiconductor structure 100. The dummy gate stack may include a layer of a material of the dummy gate insulation layers 301, 302, for example a silicon dioxide layer that is provided on surfaces of the areas 102, 103 of the substrate 101. Additionally, the dummy gate stack may include a layer of a material of the dummy gate electrodes 303, 304, for example a layer of polysilicon or a layer of amorphous silicon. In embodiments wherein the dummy gate structures 320, 321 include components other than the dummy gate insulation layers 301, 302 and the dummy gate electrodes 303, 304, the dummy gate stack may also include layers of the materials of these components. For example, in embodiments wherein the dummy gate structures 320, 321 include cap layers, the dummy gate stack may include a layer of a material of the cap layers, such as, for example, silicon nitride. For depositing the layers of the dummy gate stack, known deposition processes, such as chemical vapor deposition and/or plasma enhanced chemical vapor deposition, may be employed.

In some embodiments, the formation of the dummy gate stack may include a polishing process such as, for example, a chemical mechanical polishing process. In some embodiments, a polishing process may be performed after the completion of the deposition of the layers of the materials of the dummy gate stack. Thus, a topography of the dummy gate stack which may be caused by the recessing of the area 102 of the substrate 101 relative to the area 103 may be reduced, so that issues caused by the limited depth of focus in the patterning of the dummy gate stack by means of photolithography and etching may be reduced.

In embodiments wherein the dummy gate structures 320, 321 include cap layers, a polishing process may be performed after the deposition of the layer of the material of the dummy gate electrodes 303, 304 and before the deposition of the layer of the cap material. Thus, a substantially equal thickness of the cap layers in each of the dummy gate structures 320, 321 may be obtained. In other embodiments, the polishing process may be omitted.

After the formation of the dummy gate stack, the dummy gate stack may be patterned by means of processes of photolithography and etching for forming the dummy gate structures 320, 321.

After the formation of the dummy gate structures 320, 321, sidewall spacers 305 and 306 may be formed adjacent the dummy gate structure 320 and the dummy gate structure 321, respectively. Additionally, source regions 308, 311 and drain regions 310, 313 may be formed in the active regions 204, 205 in the areas 102, 103 of the substrate 101.

For forming the sidewall spacers 305, 306, a layer of a sidewall spacer material such as, for example, silicon nitride may be substantially isotropically deposited over the semiconductor structure 100. For this purpose, known deposition techniques such as chemical vapor deposition or plasma enhanced chemical vapor deposition may be employed. Thereafter, the layer of the sidewall spacer material may be etched anisotropically so that portions of the layer of sidewall spacer material over substantially horizontal portions of the semiconductor structure 100 are removed. Due to the anisotropy of the etch process, portions of the layer of sidewall spacer material on the sidewalls of the dummy gate structures 320, 321 remain in the semiconductor structure 100 and form the sidewall spacers 305, 306. Additionally, residues 307 of the layer of sidewall spacer material at the inclined edges of the recessed area 102 of the substrate 101 may remain in the semiconductor structure 100. Removing portions of the trench isolation structure 104 in the etch process 106, as described above with reference to FIGS. 1 and 2, may help ensure that these residues 307 of the layer of sidewall spacer material are not formed over the semiconductor material of the active region 204.

For forming the source regions 308, 311 and the drain regions 310, 313, implantation processes, wherein ions of one or more dopant materials are introduced into the active regions 204, 205, may be performed. For obtaining a desired dopant profile of the source regions 308, 311 and the drain regions 310, 313 adjacent the dummy gate structures 320, 321, the formation of the source regions 308, 311 and the drain regions 310, 313 may include both implantation processes that are performed before the formation of the sidewall spacers 305, 306 and implantation processes that are performed after the formation of the sidewall spacers 305, 306.

For obtaining different dopant profiles in the areas 102, 103 and/or for introducing different dopants into the areas 102, 103, one of the areas 102, 103 of the substrate 101 may be covered by a mask while ions are implanted into the other of the areas 102, 103.

During the implantation processes, portions of the active regions 204, 205 below the dummy gate structures 320, 321 are protected from an irradiation with dopant ions by the dummy gate structures 320, 321, so that channel regions 309, 312 having a doping that substantially corresponds to the original doping of the active regions 204, 205 are provided below the dummy gate structures 320, 321.

Then, silicide regions 314, 315, 316, 317 may be formed in the source regions 308, 311 and the drain regions 310, 313. For this purpose, a layer of a metal such as, for example, nickel may be deposited over the semiconductor structure 100, and one or more annealing processes may be performed for initiating a chemical reaction between the metal and the semiconductor material in the source regions 308, 311 and the drain regions 310, 313. Residues of unreacted metal may be removed by means of an etch process.

Thereafter, an interlayer dielectric 318 may be deposited over the semiconductor structure 100. The interlayer dielectric 318 may include an electrically non-conductive material such as, for example, silicon dioxide. The interlayer dielectric 318 may be deposited by means of a chemical vapor deposition process or a plasma enhanced chemical vapor deposition process. Then, a polishing process, for example a chemical mechanical polishing process, may be performed for obtaining a substantially planar surface of the semiconductor structure 100 and for exposing the dummy gate structures 320, 321.

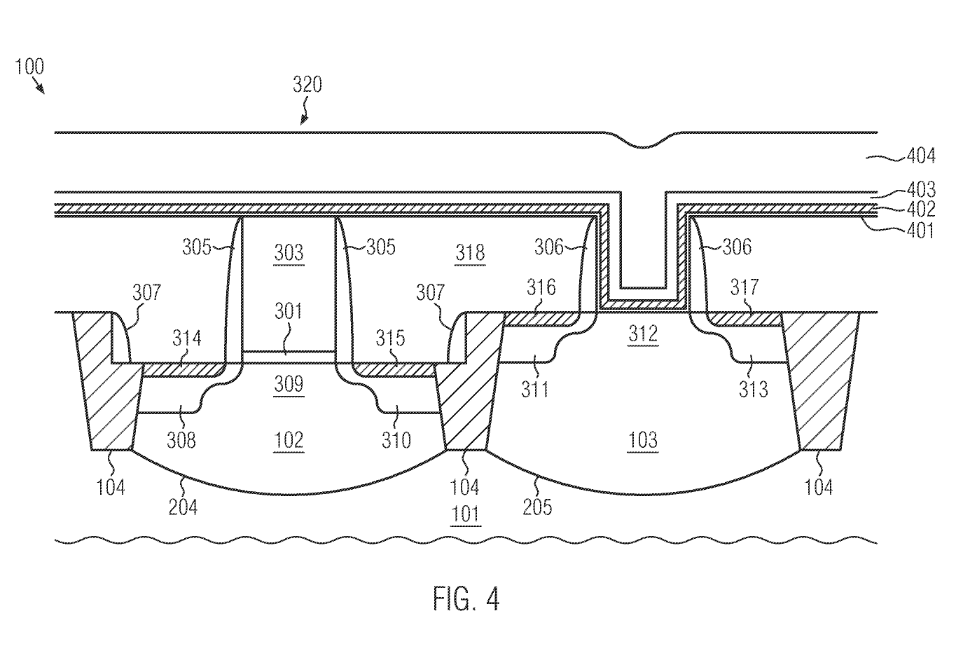

FIG. 4 shows a schematic cross-sectional view of the semiconductor structure 100 in a later stage of the manufacturing process. The dummy gate structure 321 over the active region 205 may be removed so that a recess in the semiconductor structure 100 is formed at the location of the dummy gate structure 321. For this purpose, the dummy gate structure 320 over the active region 204 may be covered by a mask, for example a photoresist mask, and one or more etch processes adapted to remove the materials of the dummy gate structure 321 may be performed. The one or more etch processes may include known dry or wet etch processes, wherein features of the one or more etch processes may correspond to those of etch processes that are performed in known replacement gate processes.

Thereafter, the mask covering the gate structure 320 may be removed, for example, by means of a photoresist strip process, and a layer 401 of a first gate insulation material, for example a silicon dioxide layer, may be deposited. Thereafter, a layer 402 of a second gate insulation material, for example a high-k gate insulation material such as hafnium dioxide, may be deposited. The deposition of the layers of gate insulation material 401, 402 may be performed by means of processes of chemical vapor deposition, plasma enhanced chemical vapor deposition and/or atomic layer deposition.

Thereafter, a layer 403 of a work function adaptation metal may be deposited. In embodiments wherein a P-channel transistor is to be formed at the area 103 of the substrate 101, the layer 403 of work function adaptation metal may include aluminum and/or aluminum nitride. In embodiments wherein an N-channel transistor is to be formed at the area 103 of the substrate 101, the layer 403 of work function adaptation metal may include lanthanum, lanthanum nitride and/or titanium nitride.

Thereafter, a layer 404 of a gate electrode material may be deposited. The layer 404 of gate electrode material may include a metal such as, for example, aluminum, or a semiconductor material such as polysilicon or amorphous silicon.

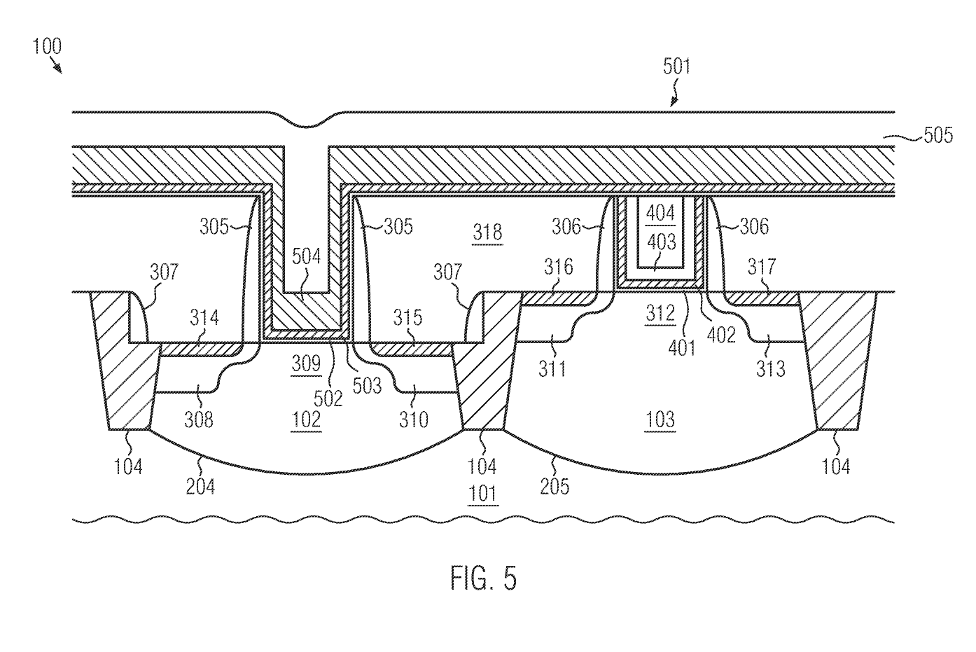

FIG. 5 shows a schematic cross-sectional view of the semiconductor structure 100 in a later stage of the manufacturing process. A chemical mechanical polishing process may be performed for removing portions of the layers 401, 402 of gate insulation material, the layer 403 of work function adaptation metal and the layer 404 of gate electrode material outside the recess of the semiconductor structure 100 that was formed by the removal of the dummy gate structure 321. Portions of the layers 401, 402, 403, 404 in the recess remain in the semiconductor structure 100 and form a gate structure 501. The gate structure 501 may be a final gate structure of the transistor 621 (FIG. 6) provided at the area 103 of the substrate 101, having a high-k metal gate configuration, the high-k material being provided by the layer 402 of gate insulation material, the metal being provided by the layer 403 of work function adaptation metal and/or the layer 404 of gate electrode material.

Then, a mask, for example, a photoresist mask, may be formed over the semiconductor structure 100. The mask covers the gate structure 501, but does not cover the dummy gate structure 320 over the area 102 of the substrate 101. Then, one or more etch processes may be performed for removing the materials of the dummy gate structure 320. Thus, a recess is formed in the semiconductor structure 100 at the location of the dummy gate structure 320.

Then, a base layer 502, which may be a silicon dioxide layer, may be formed over the semiconductor structure 100, for example by means of a chemical vapor deposition process or a plasma enhanced chemical vapor deposition process.

In some embodiments, a relatively thin layer 503 of a substantially non-ferroelectric high-k material, for example substantially non-ferroelectric hafnium dioxide, may be deposited using known deposition techniques, such as chemical vapor deposition, plasma enhanced chemical vapor deposition and/or atomic layer deposition. Parameters of the deposition process may be adapted such that a substantially non-ferroelectric crystal structure of the deposited material is obtained. In other embodiments, the layer 503 of substantially non-ferroelectric high-k material may be omitted.

Thereafter, a layer of a ferroelectric transistor dielectric 504 may be deposited over the semiconductor structure 100. The ferroelectric transistor dielectric 504 may be a material having ferroelectric properties or a material that is substantially non-ferroelectric directly after the deposition thereof but obtains ferroelectric properties after further processing steps such as, for example, an annealing process, as will be detailed below. A thickness of the layer of ferroelectric transistor dielectric 504 may be greater than a thickness of the layer 503 of substantially non-ferroelectric high-k material. In some embodiments, the ferroelectric transistor dielectric 504 may include hafnium dioxide, zirconium dioxide and/or hafnium zirconium dioxide.

The ferroelectric transistor dielectric 504 may be doped. For example, in some embodiments, the ferroelectric transistor dielectric 504 may include silicon-doped hafnium dioxide. Aluminum-doped hafnium dioxide, strontium-doped hafnium dioxide, yttrium-doped hafnium dioxide, gadolinium-doped hafnium dioxide and/or other rare earth doped hafnium oxide systems may also be employed. In further embodiments, the ferroelectric transistor dielectric 504 may include substantially undoped hafnium dioxide. In some embodiments, the deposition process used for depositing the ferroelectric transistor dielectric 504 may be adapted such that the as-deposited material is substantially amorphous and does not have ferroelectric properties.

In embodiments wherein the ferroelectric transistor dielectric 504 includes silicon-doped hafnium dioxide, an atomic layer deposition (ALD) process may be performed for depositing the ferroelectric transistor dielectric 504. In the atomic layer deposition process, tetrakis-(ethylmethylamino)-hafnium, tetrakis-dimethylamino-silane and ozone may be employed. In some embodiments, metal organic precursors and/or halide precursors may additionally be used. The atomic layer deposition may be performed at a temperature of less than 500° C., for example at a temperature in a range from about 200-400° C., in particular at a temperature of about 350° C. A silicon content of the ferroelectric transistor dielectric 504 may be in a range from about 2-5 mol %, in particular in a range from about 2.5-4.5 mol %. The silicon content of the ferroelectric transistor dielectric 504 may be controlled by varying the composition of gases employed in the atomic layer deposition process. Depositing the ferroelectric transistor dielectric 504 at a relatively low temperature as described above may help to obtain an amorphous structure of the as-deposited ferroelectric transistor dielectric 504.

In embodiments wherein the ferroelectric transistor dielectric 504 includes aluminum-doped hafnium dioxide, yttrium-doped hafnium dioxide or gadolinium-doped hafnium dioxide, an atomic layer deposition process wherein tetrakis-(ethylmethylamino)-hafnium, hafnium tetrachloride as well as ozone and/or water are used may be employed. Furthermore, depending on whether the ferroelectric transistor dielectric 504 includes aluminum, yttrium or gadolinium, trimethylaluminum, tetrakis(methylcyclopentadienyl)yttrium or tris(isopropylcyclopentane)gadolinium may be used. Further parameters of the atomic layer deposition process may correspond to those described above in the context of embodiments wherein the ferroelectric transistor dielectric 504 includes silicon-doped hafnium dioxide.

In embodiments wherein the ferroelectric transistor dielectric 504 includes substantially undoped hafnium dioxide, a chemical vapor deposition process may be used for forming the ferroelectric transistor dielectric 504, wherein materials and/or parameters corresponding to the embodiments described above are used but the substances provided for doping the ferroelectric dielectric 504 are omitted.

In embodiments wherein the ferroelectric transistor dielectric 504 includes hafnium zirconium dioxide, an atomic layer deposition process wherein tetrakis(ethylmethylamino)-zirconium, tetrakis(ethylmethylamino)hafnium and ozone are used may be performed for depositing the ferroelectric transistor dielectric 504. In some embodiments, the hafnium zirconium dioxide may have a composition in accordance with the formula HfₓZr₁₋ₓO₂, for example, a composition in accordance with the formula Hf_{0.5}, Zr_{0.5} O₂. Further parameters of the atomic layer deposition process may correspond to those described above in the context of embodiments wherein the ferroelectric transistor dielectric 504 includes silicon-doped hafnium dioxide.

In embodiments wherein the ferroelectric transistor dielectric 504 includes zirconium dioxide, deposition processes similar to those described above in the context of embodiments wherein the ferroelectric transistor dielectric 504 includes hafnium dioxide may be used, wherein reactants including zirconium are employed instead of reactants including hafnium. In particular, tetrakis(ethylmethylamino)zirconium may be used instead of tetrakis(ethylmethylamino)hafnium, and zirconium tetrachloride may be used instead of hafnium tetrachloride.

After the deposition of the ferroelectric transistor dielectric 504, a layer 505 of an electrically conductive material may be deposited. The electrically conductive material 505 may include titanium nitride, and it may be deposited using techniques such as atomic layer deposition, chemical vapor deposition, plasma enhanced chemical deposition and/or physical vapor deposition.

In some embodiments, directly after the deposition of the electrically conductive material 505, an annealing process may be performed for crystallizing the ferroelectric transistor dielectric 504. Due to the crystallization of the ferroelectric transistor dielectric 504 in the presence of the electrically conductive material 505 thereon, a crystal structure of the ferroelectric transistor dielectric 504 having ferroelectric properties may be obtained. The annealing process may be a rapid thermal annealing process wherein the semiconductor structure 100 is exposed to a temperature in a range from about 300-500° C.

The annealing process need not be performed directly after the deposition of the electrically conductive material 505. In other embodiments, the annealing process may be performed at a later point in time, for example after a process (as described below).

FIG. 6 shows a schematic cross-sectional view of the semiconductor structure 100 in a later stage of the manufacturing process. A polishing process, for example a chemical mechanical polishing process, may be performed for removing portions of the base layer 502, the layer 503 of substantially non-ferroelectric high-k material, the ferroelectric transistor dielectric 504 and the electrically conductive material 505 outside the recess of the semiconductor structure 100 that was formed by the removal of the dummy gate structure 320. Thus, a gate structure 601 over the active region 204 may be formed. The polishing process may define an upper surface of the gate structure 601 and an upper surface of the gate structure 501, which may be substantially in a same plane 602, since the polishing process can create a substantially planar surface of the semiconductor structure 100. In later stages of the manufacturing process, a further interlayer dielectric may be deposited over the semiconductor structure 100, wherein contact vias filled with an electrically conductive material such as, for example a metal, may be formed for providing electrical connections to the source regions 308, 311, the drain regions 310, 313 and the gate structures 601, 501. After these processing steps, the upper surfaces of the gate structures 601, 501 as shown in FIG. 6 become upper interfaces of the gate structures 601, 501, which lie substantially in the common plane 602.

A lower interface of the gate structure 601, which may be provided by an interface between the base layer 502 and the semiconductor material of the channel region 309, may lie substantially in the plane 202 of the surface of the recessed area 102 of the substrate 101 that was obtained after the etch process 106 described above with reference to FIG. 1. A lower interface of the gate structure 501, being provided by an interface between the layer 401 of gate insulation material and the semiconductor material of the channel region 312, may lie substantially in plane 203, which corresponds at least approximately to the surface of the area 103 of the substrate 101 at the stage of the manufacturing process described above with reference to FIG. 2. Accordingly, the lower interface of the gate structure 501 is substantially in plane 203, which is above the plane 202 of the lower interface of the gate structure 601 and spaced therefrom by the depth 201 of the recessed area 102 of the substrate 101.

A height 603 of the gate structure 601 may be greater than a height 604 of the gate structure 501, wherein a difference between the height 603 of the gate structure 601 and the height 604 of the gate structure 501 is at least approximately equal to the depth 201 of the recessed area 102 of the substrate 101.

Accordingly, the present disclosure provides a semiconductor structure having gate structures of different height, which both can be formed by means of replacement gate processes.

The present disclosure is not limited to embodiments wherein first the dummy gate structure 321 over the area 103 of the substrate 101 is replaced with the gate structure 501 of transistor 621 that does not include a ferroelectric material, and then the dummy gate structure 320 over the recessed area 102 of the substrate 101 is replaced with the gate structure 601 of the ferroelectric transistor 620. In other embodiments, first the dummy gate structure 320 may be replaced with the gate structure 601 that includes the ferroelectric transistor dielectric 504, and then the dummy gate structure 321 may be replaced with gate structure 501.

Furthermore, the present disclosure is not limited to embodiments wherein the dummy gate structures 320, 321 include dummy gate insulation layers 301, 302 which are replaced with the final gate insulation layers of the transistors 620, 621. In other embodiments, final gate insulation layers, which may include materials similar to those of the layers 401, 402, 502, 503 may be provided below the dummy gate electrodes 303, 304 and may remain in the semiconductor structure 100 when the dummy gate electrodes 303, 304 are removed and parts of the gate structures 601, 501 are formed.

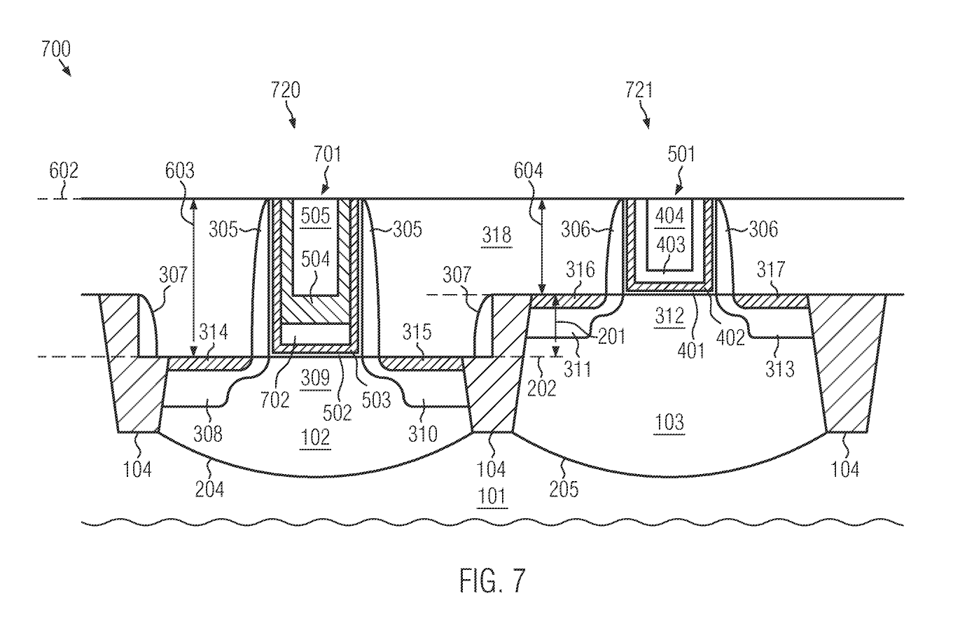

In the following, further embodiments will be described with reference to FIG. 7. FIG. 7 shows a schematic cross-sectional view of a semiconductor structure 700 according to an embodiment in a stage of a manufacturing process according to an embodiment. For convenience, in FIGS. 1-6, on the one hand, and in FIG. 7, on the other hand, like reference numerals have been used to denote like components. Unless explicitly stated otherwise, components denoted by like reference numerals may have corresponding features and substantially the same or similar techniques may be used for the formation thereof

The semiconductor structure 700 includes a substrate 101. A first area 102 of the substrate 101 is recessed relative to a second area 103 of the substrate 101 by a depth 201. A trench isolation structure 104 provides electrical insulation between the areas 102, 103 of the substrate and electrical insulation between the areas 102, 103 and areas (not shown) of the substrate 101. In the area 102, an active region 204 of a transistor 720 formed at the area 102 of the substrate 101 is provided. In the area 103, an active region 205 of a transistor 721 formed at the area 103 of the substrate 101 is provided.

The active region 204 includes a source region 308, a channel region 309 and a drain region 310. In the source region 308 and the drain region 310, silicide regions 314, 315 may be provided. The active region 205 includes a source region 311, a channel region 312 and a drain region 313. In the source region 311 and the drain region 313, silicide regions 316, 317 may be provided.

The transistor 720 provided at the area 102 of the substrate 101 includes a gate structure 701. The gate structure 701 may include a gate insulation layer including a layer 502 of a first gate insulation material, for example silicon dioxide, and a layer 503 of a second gate insulation material, for example a substantially non-ferroelectric high-k material such as substantially non-ferroelectric hafnium dioxide. Over the layers 502, 503 of gate insulation materials, a floating gate electrode 702 may be provided. The floating gate electrode 702 may include an electrically conductive material, for example a metal such as titanium nitride. In other embodiments, the floating gate electrode 702 may be formed of a semiconductor material such as, for example, polysilicon or amorphous silicon. In further embodiments, the floating gate electrode 702 may include a layer of a metal such as, for example, titanium nitride and a layer of a semiconductor material such as polysilicon or amorphous silicon that is formed above the metal layer.

The gate structure 701 may further include a ferroelectric transistor dielectric 504. In some embodiments, the ferroelectric transistor dielectric 504 may include an oxide of hafnium and/or zirconium. Over the ferroelectric transistor dielectric 504, an electrically conductive gate electrode material 505 providing a control gate electrode of the transistor 720, for example, a metal such as titanium nitride, may be provided.

At the stage of the manufacturing process illustrated in FIG. 7, the ferroelectric transistor dielectric 504 may have ferroelectric properties so that it is a ferroelectric material. In some embodiments, the ferroelectric properties of the ferroelectric transistor dielectric 504 may be obtained by annealing the semiconductor structure 700 after the deposition of the gate electrode material 505 so that a re-crystallization of the ferroelectric transistor dielectric 504 in the presence of the gate electrode material 505 occurs, wherein a crystal structure of the ferroelectric transistor dielectric 504 having ferroelectric properties is obtained, similar to the annealing process described above with reference to FIG. 5.

Adjacent the gate structure 701, a sidewall spacer 305 may be provided. Residues 307 of a sidewall spacer material from which the sidewall spacer 305 is formed may also be present at the edges of the recess at the area 102 of the substrate 101, for example over recessed portions of the trench isolation structure 104 adjacent the area 102.

The transistor 721 provided at the area 103 of the substrate 101 includes a gate structure 501 provided over the channel region 312. The gate structure 501 may include a gate insulation layer formed by a layer 401 of a first gate insulation material, for example silicon dioxide, and a layer 402 of a second gate insulation material, for example a substantially non-ferroelectric high-k gate insulation material such as substantially non-ferroelectric hafnium dioxide. Above the layers 401, 402 of gate insulation material, a work function adaptation metal 403, being a first gate electrode material, and a layer 404 of another gate electrode material, for example a metal, such as aluminum, or a semiconductor material, such as polysilicon or amorphous silicon, may be provided. Adjacent the gate structure 501, a sidewall spacer structure may can be provided.

An upper interface of the gate structure 701 of the transistor 720 and an upper interface of the gate structure 501 of the transistor 721 may be substantially in a same plane 602. At the stage of the manufacturing process shown in FIG. 7, the upper interfaces of the gate structure 701, 501 are at the surface of the semiconductor structure 700.

A lower interface of the gate structure 701, being an interface between the layer 502 of first gate insulation material and the semiconductor material of the channel region 309, may be substantially in a plane 202, and a lower interface of the gate structure 501 of the transistor 721, being an interface between the layer 401 of first gate insulation material and the semiconductor material of the channel region 312, may be substantially in plane 203. The plane 203 is above the plane 202, the planes 203, 202 being spaced apart from each other by the depth 201 of the recessed area 102 of the substrate 101.

For forming the semiconductor structure 700, methods as described above with reference to FIGS. 1-6 may be performed, wherein, after the deposition of the layers 502, 503 of gate insulation material and before the deposition of the layer 504 of the ferroelectric transistor dielectric, one or more layers of the material of the floating gate electrode 702 may be deposited.

In some embodiments, for depositing the one or more materials of the floating gate electrode 702, an anisotropic deposition process may be performed, wherein thicknesses of the as-deposited layers of the one or more materials of the floating gate electrode 702 at the sidewalls of the sidewall spacer 305 are smaller than a thickness of substantially horizontal portions of the layers of the one or more materials of the floating gate electrode 702 over the channel region 309.

In some embodiments, one or more substantially isotropic etch processes may then be performed for removing the one or more materials of the floating gate electrode 702 at the sidewalls of the sidewall spacer 305 to obtain a configuration of the floating gate electrode 702 as illustrated in FIG. 7. This may help to avoid inadvertently providing an electrical contact to the floating gate electrode 702 when a contact via filled with an electrically conductive material contacting the control gate electrode provided by the gate electrode material 505 is formed.

In other embodiments, portions of the one or more materials of the floating gate electrode 702 at the sidewalls of the sidewall spacer 305 may remain in the semiconductor structure 700.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed:

1. A method, comprising:
providing a substrate comprising a semiconductor material;
recessing a first area of said substrate relative to a second area of said substrate;
forming an active region of a first transistor in said recessed first area of said substrate;
forming an active region of a second transistor in said second area of said substrate;
forming a first dummy gate structure over said active region of said first transistor;
forming a second dummy gate structure over said active region of said second transistor;
replacing at least a portion of said first dummy gate structure with at least a portion of a gate structure of said first transistor; and
replacing at least a portion of said second dummy gate structure with at least a portion of a gate structure of said second transistor;
wherein said gate structure of said first transistor comprises a ferroelectric material and said gate structure of said second transistor does not comprise a ferroelectric material.

2. The method of claim 1, wherein said recessing said first area of said substrate relative to said second area of said substrate comprises:
forming a mask over said substrate, wherein said mask covers said second area of said substrate but not said first area of said substrate; and
performing an etch process adapted to remove said semiconductor material of said substrate.

3. The method of claim 2, wherein said etch process is adapted to remove such an amount of said semiconductor material of said substrate that said first area of said substrate is recessed relative to said second area of said substrate by a depth, said depth being at least approximately equal to a difference between a height of said gate structure of said first transistor and a height of said gate structure of said second transistor.

4. The method of claim 3, wherein a polishing process defining an upper interface of said gate structure of said first transistor and an upper interface of said gate structure of said second transistor is performed.

5. The method of claim 4, wherein the replacement of said first dummy gate structure with said at least a portion of said gate structure of said first transistor comprises depositing a layer of a ferroelectric transistor dielectric, wherein said ferroelectric material of said gate structure of said first transistor is formed from said layer of ferroelectric transistor dielectric.

6. The method of claim 5, wherein said ferroelectric transistor dielectric comprises an oxide of at least one of hafnium and zirconium.

7. The method of claim 6, wherein the replacement of said first dummy gate structure with said at least a portion of said gate structure of said first transistor further comprises depositing a first layer of an electrically conductive material after the deposition of said ferroelectric transistor dielectric and forming a first gate electrode of said first transistor from said first layer of electrically conductive material.

8. The method of claim 7, wherein the replacement of said first dummy gate structure with said at least a portion of said gate structure of said first transistor further comprises depositing a second layer of an electrically conductive material before the deposition of said ferroelectric transistor dielectric and forming a second gate electrode of said first transistor from said second layer of electrically conductive material, wherein said first gate electrode is a control gate electrode and said second gate electrode is a floating gate electrode.

9. The method of claim 7, wherein the replacement of said first dummy gate structure with said at least a portion of said gate structure of said first transistor further comprises:
depositing a silicon dioxide layer; and
depositing a layer of a substantially non-ferroelectric high-k material over said silicon dioxide layer;
wherein said ferroelectric transistor dielectric is deposited after the deposition of said layer of substantially non-ferroelectric transistor dielectric.

10. The method of claim 9, wherein the replacement of said second dummy gate structure with said at least a portion of said gate structure of said second transistor comprises forming a gate insulation layer comprising a high-k material having a greater dielectric constant than silicon.

11. The method of claim 10, wherein the replacement of said second dummy gate structure with said at least a portion of said gate structure further comprises forming a metal layer over said gate insulation layer.

12. The method of claim 11, wherein a memory cell comprising said first transistor is provided, the method further comprising providing a remanent polarization of said ferroelectric material of said gate structure of said first transistor that is representative of data stored in said memory cell.

13. A semiconductor structure, comprising:
a semiconductor substrate;
a first transistor comprising an active region and a gate structure arranged over said active region, wherein said gate structure of said first transistor comprises a floating gate electrode, a ferroelectric material provided over said floating gate electrode and a control gate electrode provided over said ferroelectric material; and
a second transistor comprising an active region and a gate structure arranged over said active region, wherein said gate structure of said second transistor does not comprise a ferroelectric material;
wherein said active region of said first transistor is provided in a first area of said substrate and said active region of said second transistor is provided in a second area of said substrate, said first area being recessed relative to said second area.

14. The semiconductor structure of claim 13, wherein said first area is recessed relative to said second area by a depth, wherein said gate structure of said first transistor has a greater height than said gate structure of said second transistor, and wherein a difference between the height of said gate structure of said first transistor and the height of said gate structure of said second transistor is at least approximately equal to said depth.

15. The semiconductor structure of claim 14, wherein an upper interface of said gate structure of said first transistor is substantially in a same first plane as an upper interface of said gate structure of said second transistor.

16. The semiconductor structure of claim 15, wherein a lower interface of said gate structure of said first transistor is substantially in a second plane and a lower interface of said gate structure of said second transistor is substantially in a third plane, said third plane being above said second plane.

17. The semiconductor structure of claim 16, wherein said first transistor is part of a nonvolatile memory cell, a remanent polarization of said ferroelectric material being representative of data stored in said nonvolatile memory cell.

18. The semiconductor structure of claim 17, wherein said ferroelectric material comprises an oxide of at least one of hafnium and zirconium.

19. The semiconductor structure of claim 18, wherein at least said gate structure of said second transistor comprises a gate insulation layer comprising a high-k material having a greater dielectric constant than silicon.

20. The semiconductor structure of claim 19, wherein at least said gate structure of said second transistor comprises a gate electrode comprising a metal.

21. The semiconductor structure of claim 20, wherein said gate structure of said first transistor further comprises:
a layer of a substantially non-ferroelectric high-k material below said ferroelectric material; and
a layer of silicon dioxide below said layer of substantially non-ferroelectric high-k material.
